(19) United States
(12) Patent Application Publication
(10) Pub. No.: US 2025/0233069 A1
(43) Pub. Date: Jul. 17, 2025

(54) SEMICONDUCTOR STRUCTURE WITH ULTRA THICK METAL AND MANUFACTURING METHOD THEREOF

(71) Applicant: TAIWAN SEMICONDUCTOR MANUFACTURING COMPANY, LTD., Hsinchu (TW)

(72) Inventors: Jyun-Min Syu, Taichung (TW); Ming Chen Hung, Taichung (TW); Chih-Hsiao Chen, Taichung (TW); Yi-Lii Huang, Zhubei (TW); Ching-Chung Hsu, Taichung (TW); Yi-Chen Li, Taichung (TW)

(21) Appl. No.: 18/413,314

(22) Filed: Jan. 16, 2024

(51) Int. Cl. H01L 23/528; H01L 21/768; H01L 23/522

(52) U.S. Cl. CPC H01L 23/5283; H01L 21/76802; H01L 21/7684; H01L 21/76846; H01L 21/76877; H01L 23/5226

(57) ABSTRACT

A semiconductor device structure is provided. The structure includes a device layer, an interconnect structure comprising a plurality of back-end-of-line (BEOL) metal layers disposed over the device layer, and an ultra-thick-metal (UTM) structure disposed over the interconnect structure. The UTM structure includes a first UTM feature having a first width, and a second UTM feature disposed around the first UTM feature, wherein the second UTM feature has a second width less than the first width, and the second UTM feature is separated from the first UTM feature by a dielectric material.

### BACKGROUND

The semiconductor integrated circuit (IC) industry has produced a wide variety of devices to address issues in a number of different areas, including radio frequency (RF) communications. While growing in popularity, improving RF integrated circuits puts particular demands on the semiconductor process. Some RF circuits employ thick metal layers for inductive and other properties. However, the device geometry of new generations of ICs with smaller dimensions created new limiting factors. Therefore, improved semiconductor device structures and processing techniques are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of one of various stages of manufacturing a semiconductor device structure, in accordance with some embodiments.

FIG. 1B is a cross-sectional side view of the stage of manufacturing the semiconductor device structure taken along line B-B of FIG. 1A, in accordance with some embodiments.

FIGS. 2-6, 9-12, and 15 are cross-sectional side views of various stages of manufacturing the semiconductor device structure, in accordance with some embodiments.

FIGS. 7A and 7B are top-views of a portion of the semiconductor device structure taken along cross-section A-A of FIG. 6, in accordance with some embodiments.

FIG. 8 is a top-view of a portion of the semiconductor device structure taken along cross-section B-B of FIG. 6, in accordance with some embodiments.

FIGS. 13A and 13B are top-views of a portion of the semiconductor device structure taken along cross-section C-C of FIG. 12, in accordance with some embodiments.

FIG. 14 is a top-view of a portion of the semiconductor device structure taken along cross-section D-D of FIG. 12, in accordance with some embodiments.

FIG. 16 illustrates a perspective view of a portion of the first UTM structure and a portion of the second UTM structure, in accordance with the embodiment shown in FIG. 16.

FIGS. 17-23 illustrate exemplary configurations of UTM structures in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

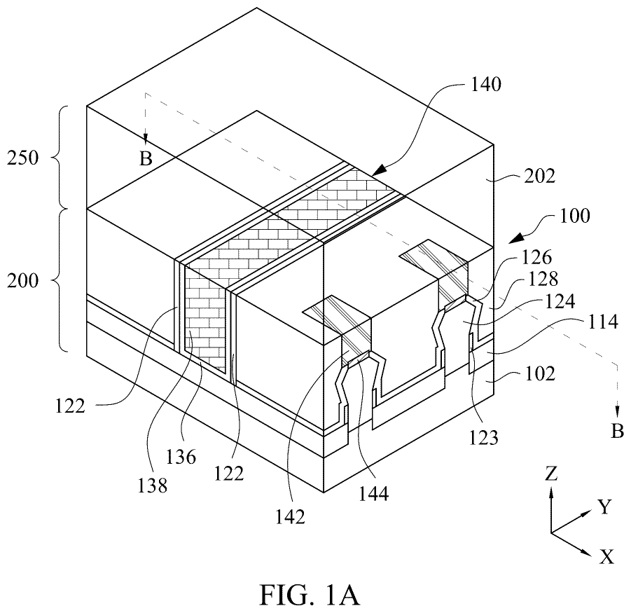

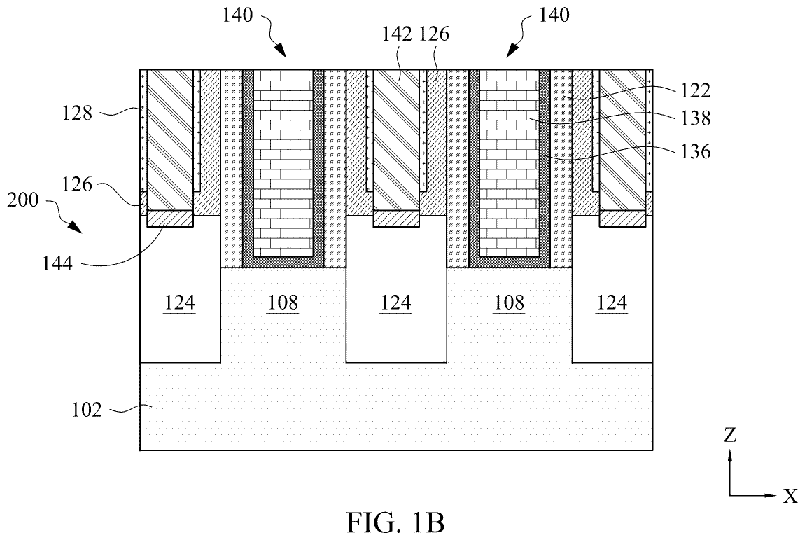

FIG. 1A illustrates a stage of manufacturing a semiconductor device structure 100 including a device layer 200 and an interconnect structure 250. FIG. 1B illustrates a cross-sectional view of the device layer 200 in accordance with some embodiments. The device layer 200 includes a substrate 102 and one or more devices formed in or on the substrate 102. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of silicon.

The substrate 102 may include various regions that have been suitably doped with impurities (e.g., p-type or n-type impurities). The dopants are, for example phosphorus for an n-type fin field effect transistor (FinFET) and boron for a p-type FinFET.

The device layer 200 may include any suitable devices, such as transistors, diodes, imaging sensors, resistors, capacitors, inductors, memory cells, or a combination thereof. In some embodiments, the device layer 200 includes transistors, such as planar field effect transistors (FETs), FinFETs, complementary FETs (CFETs), forksheet FETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device formed on the substrate 102 is a FinFET, which is shown in FIGS. 1A and 1B. The device layer 200 includes source/drain (S/D) regions 124 and gate stacks 140 (only one is shown in FIG. 1A). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. As shown in FIG. 1B, two gate stacks 140 are formed on the substrate 102. In some embodiments, more than two gate stacks 140 are formed on the substrate 102. While not shown, channel regions are formed between the S/D regions 124 and have at least three surfaces wrapped around by the gate stack 140.

The S/D regions 124 may include a semiconductor material, such as Si or Ge, a III-V compound semiconductor, a II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions may include one or more semiconductor materials, such as Si, Ge, GeSn, SiGe, GaAs, InSb, GaP, GaSb, InAlAs, InGaAs, GaSbP, GaAsSb, GaN, GaP, or InP. The channel regions may include the same semiconductor material as the substrate 102. In some embodiments, the device layer 200 may include FinFETs, and the channel regions are a plurality of fins disposed below the gate stacks 140. In some embodiments, the device layer 200 may include nanostructure transistors, and the channel regions are surrounded by the gate stacks 140.

As shown in FIGS. 1A and 1B, each gate stack 140 includes a gate electrode layer 138 disposed over the channel region (or surrounding the channel region for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. The gate stack 140 may further include a gate dielectric layer 136 disposed over the channel region. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layer 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique. In some embodiments, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

A contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

S/D contacts 142 may be disposed in the ILD layer 128 and over the S/D region 124. The S/D contacts 142 may be electrically conductive and include a material having one or more of Ru, Mo, Co, Ni, W, Ti, Ta, Cu, Al, TiN or TaN, and the conductive contact may be formed by any suitable method, such as electro-chemical plating (ECP), or PVD. A silicide layer 144 may be disposed between the S/D contacts 142 and the S/D region 124. The silicide layers 144 may be made of a metal or metal alloy silicide, and the metal includes a noble metal, a refractory metal, a rare earth metal, alloys thereof, or combinations thereof.

In integrated circuits, interconnection structures (or interconnect structures) are used to provide signal routing and power supply to semiconductor devices. An integrated circuit chip typically includes a device layer, fabricated during front-end-of-line (FEOL) and middle-end-of-line (MEOL) processes, and a back-end-of-line (BEOL) layer. The device layer may be formed in and/or on the substrate, and the BEOL layer is formed on a front side and/or backside of the device layer. The device layer may include various semiconductor devices, such as transistors, diodes, capacitors, resistors, etc., and may be formed in and/or on the substrate. In some embodiments, the device layer may also include the MEOL structures, such as one or more dielectric layers with conductive features connected to gates and source/drain features in the device layer. Interconnection structures typically include conductive lines and vias formed in both the device layer and the BEOL layers.

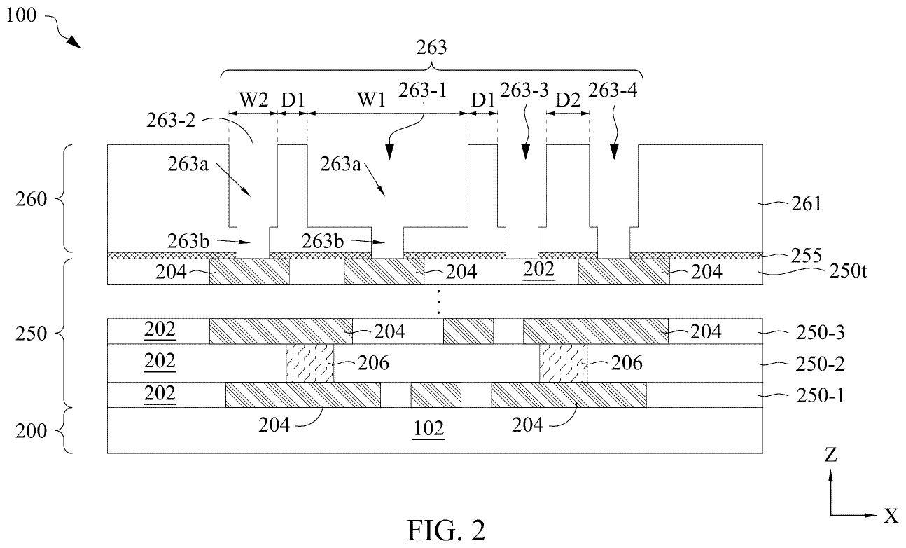

FIGS. 2-6, 9-12, and 15-16 are cross-sectional side views of various stages of manufacturing the semiconductor device structure 100, in accordance with some embodiments. In FIG. 2, the interconnect structure 250, which includes metal features such as metal lines 204 and vias 206, is disposed over the device layer 200 and the substrate 102. The interconnect structure 250 has a plurality of BEOL metal layers, namely M1 250-1, M2 250-2, M3 250-3, . . . , Mtop 250-t. The metal layer M1 250-1 may be a layer immediately above the ILD layer 128, while the metal layer Mtop 250-t may be a top metal layer that is immediately under a first ultra-thick-metal (UTM) structure 260, which is formed in the subsequent steps. In most cases, the metal features in the top metal layer Mtop 250-t are thicker than those in the underlying layers, such as the M1 250-1. Throughout the present disclosure, the term “metal layer” refers to the collection of the metal features in the same layer. Metal layers M1 250-1 through Mtop 250-t are formed in inter-metal dielectric (IMD) layers 202, which may be formed of oxides such as un-doped silicate glass (USG), fluorinated silicate glass (FSG), low-k dielectric materials, or the like. The IMD layers 202 may be formed by CVD, FCVD, ALD, spin coating, or other suitable process. The low-k dielectric materials may have a k value ranging from about 1 to about 4. The IMD layers 202 provide isolation functions to various metal lines 204 and vias 206.

While not shown, it is contemplated that the bottom-most metal feature (e.g., metal lines 204) of the interconnect structure 250 may be electrically connected to the conductive contacts disposed over the S/D regions 124 (FIGS. 1A and 1B) and the gate electrode layer 138 (FIGS. 1A and 1B). For example, one or more metal lines 204 may be electrically connected to the S/D contacts 142 disposed in the ILD 128 of the device layer 200. In some embodiments, a backside interconnection structure (not shown), similar to the interconnect structure 250, may be formed on the backside of the device layer 200 to provide power supply and/or additional signal connection to the device layer 200.

In some embodiments, the metal layer M1 250-1 may have a thickness between about 300 Å and about 800 Å, and the metal layers M2 250-2 through Mtop 250-t each may have a thickness between about 500 Å and about 1000 Å. However, the dimensions described in this disclosure are merely examples, and may be changed in alternative embodiments.

After formation of the interconnect structure 250, a first etch stop layer 255 and a first dielectric material 261 are sequentially formed over the top metal layer Mtop 250-t. The first etch stop layer 255 is in contact with the metal lines 204 in the top metal layer Mtop 250-t. In some embodiments, the first etch stop layer 255 is disposed at the interface of the subsequently formed first UTM structure 260 and the top metal layer Mtop 250-t. The first etch stop layer 255 may include a material different from the first dielectric material 261 in order to have different etch selectivity compared to the first dielectric material 261. In some embodiments, the first etch stop layer 255 is made of a dielectric material, such as an oxide, a nitride, a metal oxide, a metal nitride, or a combination thereof. Suitable materials for the first etch stop layer 255 may include, but not limited to, silicon nitride, silicon carbide, oxygen-doped silicon carbide (ODC), silicon carbon nitride, silicon oxynitride, carbon nitride, silicon oxide, silicon carbon oxide, and aluminum oxide, etc. The first etch stop layer 255 may be a single layer or a multi-layer structure. The first etch stop layer 255 may be formed by any suitable process, such as CVD, ALD, PVD, PEALD, or PECVD. The first dielectric material 261 may include the same material as the IMD layers 202 and may be formed by the same process as the IMD layers 202. The first etch stop layer 255 may have a thickness between about 100 Å and about 2000 Å. The first dielectric material 261 may include the same material as the IMD layer 202 and may be formed by the same process as the IMD layer 202. The first dielectric material 261 may have a thickness between about 1000 Å and about 68000 Å, for example about 8000 Å to about 35000 Å.

After the first etch stop layer 255 and the first dielectric material 261 are formed, openings 263a, 263b are formed in and through the first dielectric material 261. The openings 263a, 263b combined form ultra-thick-metal (UTM) trenches 263-1, 263-2, 263-3, 263-4 (collectively referred to as 263). In some embodiments, the two or more UTM trenches may be part of a continuous trench. For example, the UTM trench 263-2 and the UTM trench 263-3 may belong to a continuous trench. In some embodiments, the UTM trenches 263-2, 263-3 is a continuous trench arranged to surround the UTM trench 263-1. While four UTM trenches 263-1 to 263-4 are shown, more or less UTM trenches are contemplated depending on the application. The UTM trenches 263-1 to 263-4 are intended to be filled with a conductive material to form UTM features therein. The openings 263a, 263b may be formed by any suitable process, such as one or more etch processes. In some embodiments, the openings 263a, 263b are formed as a result of a dual-damascene process. The opening 263a may be a trench opening formed in an upper portion of the first dielectric material 261. The opening 263b may be a via opening formed through the first dielectric material 261 and the first etch stop layer 255 to expose a portion of the corresponding metal lines 204.

The UTM trenches 263-1 to 263-4 are formed so that the UTM trench 263-1 and the UTM trenches 263-2 and 263-3 are separated by a distance D1, and the UTM trench 263-3 and the UTM trench 263-4 are separated by a distance D2. In some embodiments, the distance D1 is substantially identical to the distance D2. In some embodiments, the distance D1 is greater or less than the distance D2. The UTM trenches 263-1 to 263-4 may have a width ranging from 0.1 μm to about 50 μm. The UTM trench 263-1 may have a width W1 and the trenches 263-2, 263-3, 263-4 may have a width W2 that is less than the width W1. In some embodiments, the width W1 and width W2 may be at a ratio (W1:W2) of about 2:1 or greater, for example about 3:1 to about 6:1, for example about 4:1. In some embodiments, the width W2 may be in a range of about 0.2 μm to about 10 μm, and the distance D1 may be about 0.2 m or greater. The UTM trench 263-1 with a greater width allows the subsequent UTM feature 266-1 to form therein with a greater size. As a result, the inductor as formed can provide a lower DC resistance.

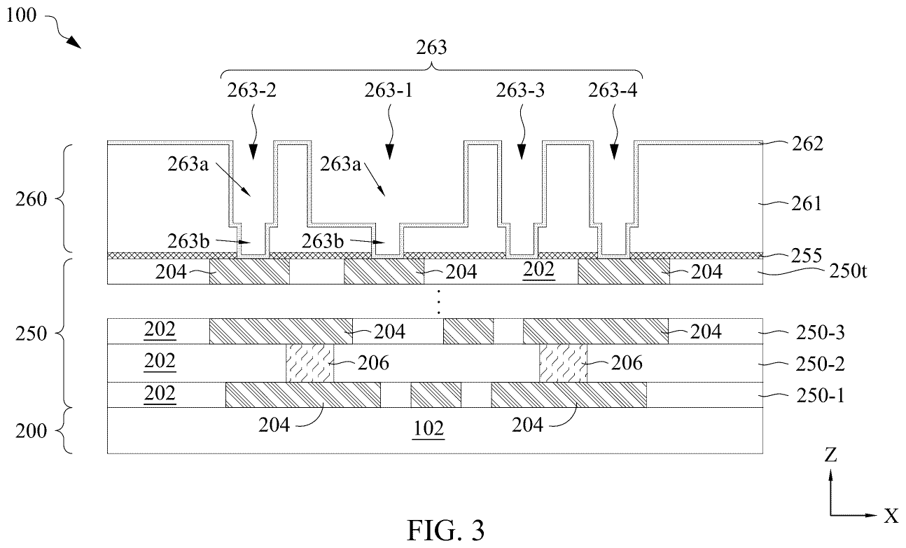

In FIG. 3, a barrier layer 262 is conformally formed on exposed surfaces of the first dielectric material 261. The barrier layer 262 may be formed on the top surface of the first dielectric material 261 and the sidewall surfaces within the openings 263a, 263b, including an exposed surface of the metal lines 204 at a bottom portion of the opening 263b. The barrier layer 262 serves as a diffusion barrier which prevents metal from diffusing into surrounding materials such as the first dielectric material 261, the first etch stop layer 255, and the metal lines 204. The barrier layer 262 can be blanket deposited using any suitable deposition technique, such as CVD, PVD, ion metal plasma (IMP), or self-ionized plasma (SIP). The barrier layer 262 may include metal nitride, metal oxide, two-dimensional (2D) material, or a combination thereof. Suitable metals for the barrier layer 262 may include, but are not limited to, Ta, Ti, W, Mn, Zn, Cr, In, or Hf. In some embodiments, the barrier layer 262 is a metal nitride, such as TaN, TiN, WN, CrN, TaSiN, TiSiN, WSiN, or a metal oxide, such as HfOx. The term “2D material” used in this disclosure refers to single layer material or monolayer-type material that is atomically thin crystalline solid having intralayer covalent bonding and interlayer van der Waals bonding. Examples of a 2D material may include graphene, hexagonal boron nitride (h-BN), or transition metal dichalcogenides (MX₂), where M is a transition metal element and X is a chalcogenide element. Some exemplary MX₂ materials may include, but are not limited to Hf, Te₂, WS₂, MoS₂, WSe₂, MoSe₂, or any combination thereof. The barrier layer 262 may have a thickness ranging from about 3 Å to about 3000 Å.

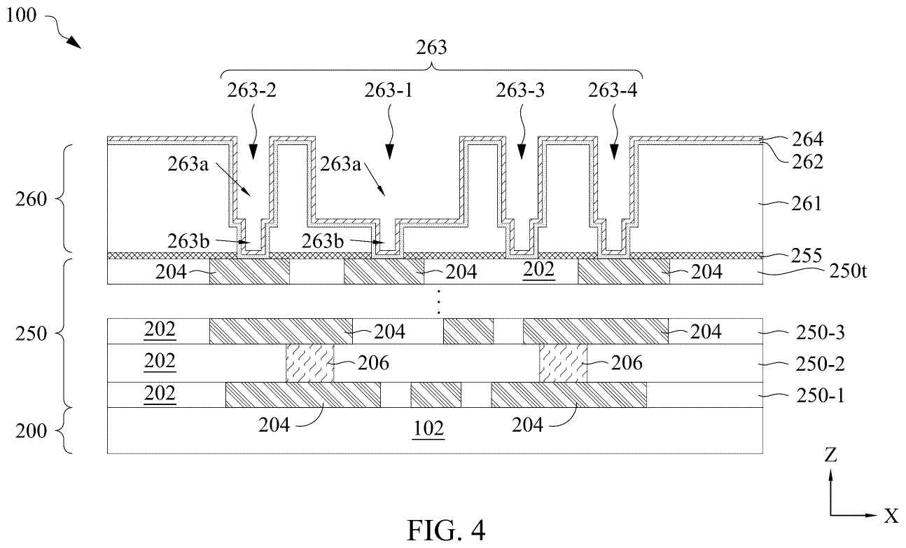

In FIG. 4, a seed layer 264 is formed on the barrier layer 262. The seed layer 264 assists formation of the subsequent conductive material to be filled in the openings 263a, 263b. The seed layer 264 may be a metal such as Cu, Al, Ti, Au, Mn, Fe, an alloy, or other suitable material that accepts an electroplated layer. The seed layer 264 may be formed by ALD, PEALD, CVD, PECVD, or other suitable deposition techniques. The seed layer 264 may have a thickness ranging from about 100 Å to about 2000 Å.

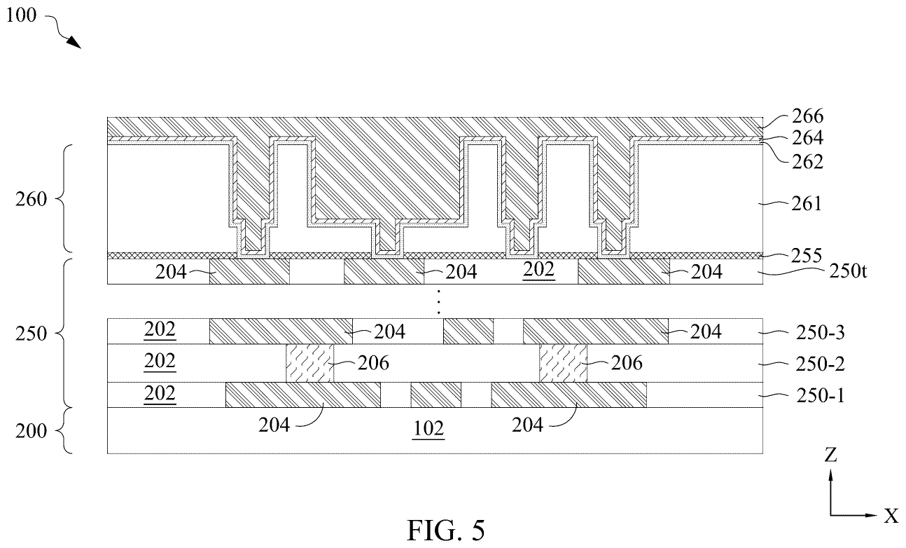

In FIG. 5, an UTM layer 266 is formed on the seed layer 264. The UTM layer 266 is deposited until the UTM trenches 263-1 to 263-4 are completely filled. The UTM layer 266 may include an electrically conductive material such as Cu, Al, Ag, Fe, Mn, Co, Ru, Zn, Zr, W, Mo, Os, Ir, Ni, alloys thereof, or combinations thereof. In some embodiments, the UTM layer 266 includes AlCu, CuAg, CuAl, CuMn, or CoRu. In one exemplary embodiment, the UTM layer 266 is a copper-silver alloy, in which silver has an atomic percentage of about 5 at. % or greater. The UTM layer 266 fills in the openings 263a, 263b, and is deposited to a height over the top surface of the first dielectric material 261. The UTM layer 266 in the openings 263a, 263b is surrounded by the first dielectric material 261. The UTM layer 266 may be deposited using PVD, CVD, ALD, electroplating, or other suitable deposition process, or combinations thereof. In some embodiments, the UTM layer 266 formed in the UTM trench 263-1 includes a first electrically conductive material and the UTM layer 266 formed in the UTM trenches 263-2 to 263-4 includes a second electrically conductive material that is different than the first electrically conductive material.

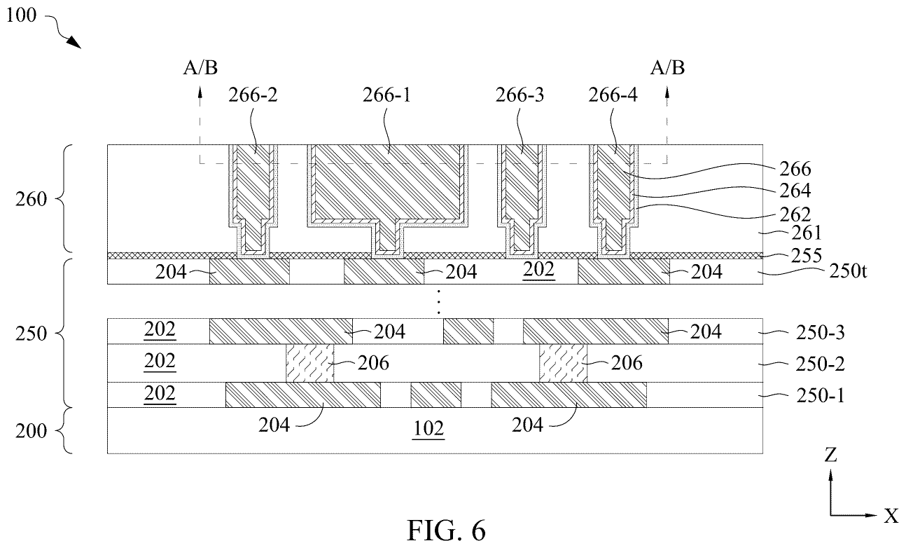

In FIG. 6, a planarization process, such as a CMP process, is performed on the semiconductor device structure 100 to remove the excess UTM layer 266 over the top surface of the first dielectric material 261. After the planarization process, the top surfaces of the first dielectric material 261, the barrier layer 262, the seed layer 264, and the UTM layer 266 are substantially co-planar. The UTM layer 266 in the UTM trenches 263-1 to 263-4 form UTM features 266-1, 266-2, 266-3, 266-4, and the UTM features 266-1 to 266-4 are separated from one another other by the first dielectric material 261. The UTM features 266-1 to 266-4 (and other UTM features, not shown) in the first dielectric material 261 form the first UTM structure 260. The first UTM structure 260 may have a first thickness, and the conductive features (e.g., metal lines 204) in the metal layer M1 250-1 of the interconnect structure 250 may have a second thickness significantly less than the first thickness. The term “UTM layer” in this disclosure may be referred to the collection of all UTM features in the first dielectric material 261. In various embodiments, the UTM features 266-2 to 266-4 are arranged in a planar coil-like pattern to help enhance the magnetic field intensity of an inductor.

The UTM features 266-1 to 266-4 or the first UTM structure 260 may form a portion of an inductor when the semiconductor device structure 100 includes, or is used as a radio frequency (RC) device. The UTM features 266-1 to 266-4 may be considered as a discrete inductor since the UTM features 266-1 to 266-4 are isolated from the device layer 200 and the interconnect structure 250 by the barrier layer 262, the first dielectric material 261, and the first etch stop layer 255. In some embodiments, the UTM features 266-1 to 266-4 form a portion of a capacitor. In some embodiments, the UTM features 266-1 to 266-4 form a portion of a power line. The UTM features 266-1 to 266-4 are electrically connected to various conductive features (e.g., metal lines 204) in the interconnect structure 250. In some embodiments, the UTM features 266-1 to 266-4 are electrically connected to various devices in the device layer 200 through an external routing (not shown), such as a wire bond.

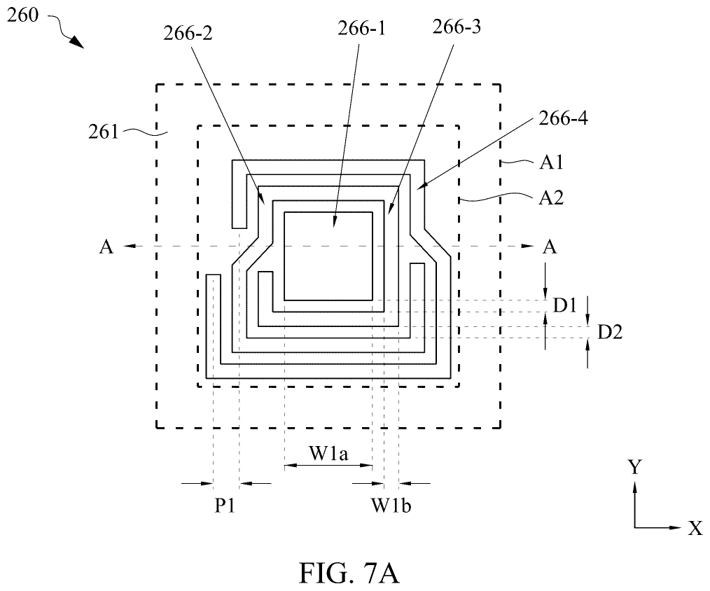

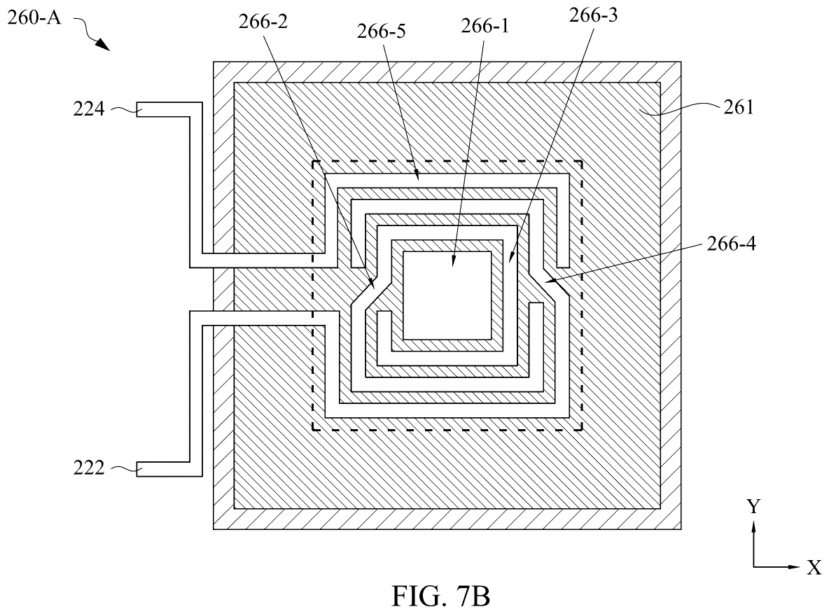

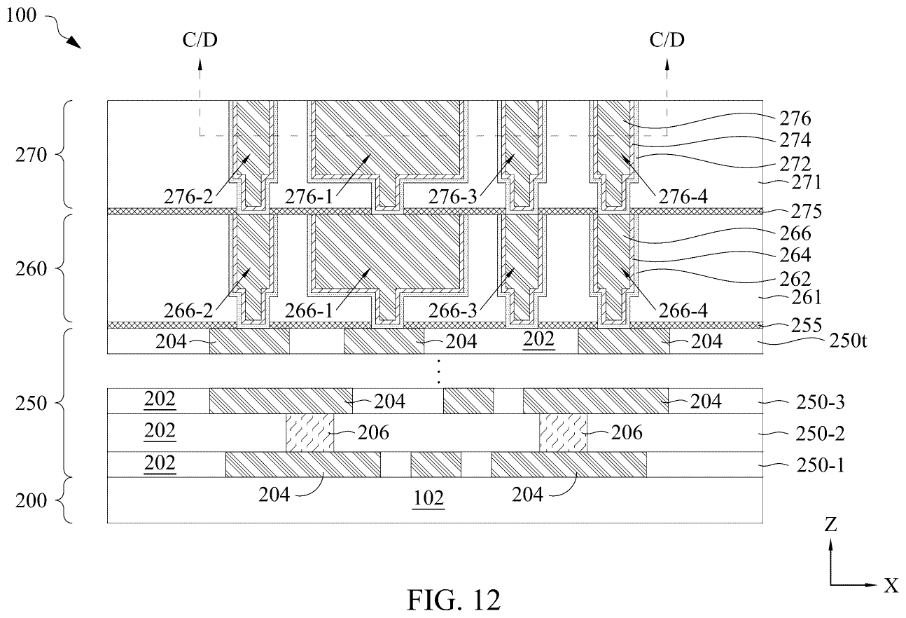

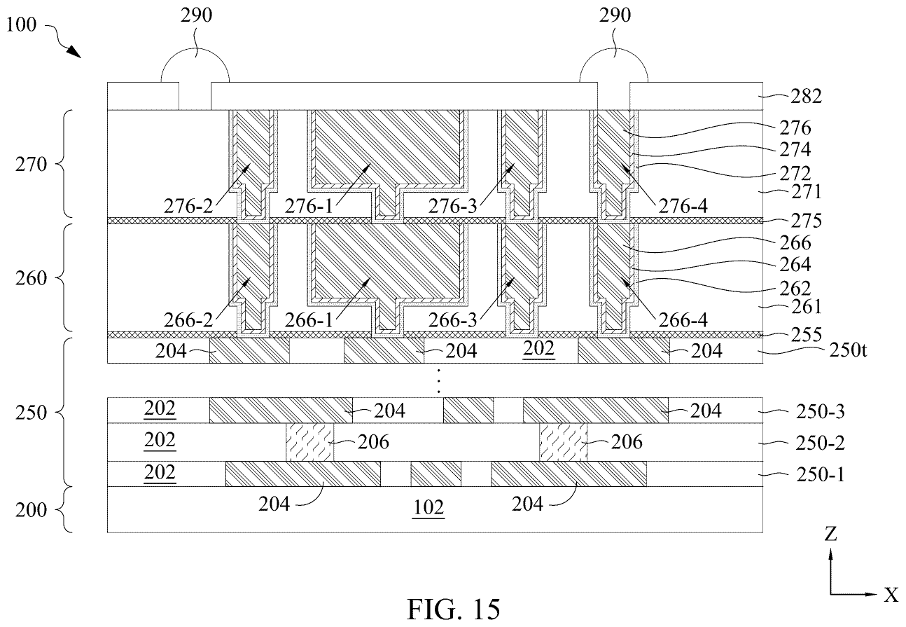

FIG. 7A is a top view of a portion of the semiconductor device structure 100 showing the first UTM structure 260 taken along cross-section A-A of FIG. 6, in accordance with some embodiments. As can be seen, the UTM features 266-2 to 266-4 are discrete metal lines arranged in a planar coil-like pattern. In some embodiments, the UTM features 266-2 and 266-3 are constructed as a continuous metal line surrounding the UTM feature 266-1, and the UTM feature 266-4 is constructed as a continuous metal line around the UTM features 266-2 and 266-3. The UTM features 266-2 to 266-4 may have the same width. The UTM features 266-2 to 266-4 may be arranged asymmetric so that the number of the metal lines on a first side of the UTM feature 266-1 is different than the number of the metal lines on a second side (opposing the first side) of the UTM feature 266-1. The UTM feature 266-1 and the UTM feature 266-2 or 266-3 are separated from each other by the distance D1, and the UTM feature 266-2 or 266-3 and the UTM feature 266-4 are separated from each other by the distance D2. Depending on the application, the distance D1 may be less, equal to, or greater than the distance D2. In some embodiments, the UTM feature 266-1 may be a pillar-like structure. While a square-shaped pillar is shown, the UTM feature 266-1 can be other shape, such as a round-shaped, a rectangular-shaped, or an oval-shaped pillar when viewing from top. While not shown, in some embodiments, the UTM feature 266-4 may have a first end in electrical connection with conductive features (e.g., metal lines 204), and a second end in electrical connection with conductive terminals, such as conductive structures 290 shown in FIG. 15. Additionally or alternatively, the second end may be in electrical connection with UTM features (e.g., UTM feature 276-4) of the second UTM structure 270, as shown in FIG. 12.

FIG. 7B is a top view of a portion of the semiconductor device structure 100 showing a first UTM structure 260-A, such as the first UTM structure 260, taken along cross-section A-A of FIG. 6, in accordance with some alternative embodiments. In this embodiment, the UTM features 266-2 to 266-4 are arranged in a symmetric manner so that the number of the metal lines on a first side of the UTM feature 266-1 is identical to the number of the metal lines on a second side (opposing the first side) of the UTM feature 266-1. FIG. 7B further shows that one of the outermost UTM features (e.g., UTM feature 266-4) has an end 222 in electrical connection with conductive terminals, such as conductive structures 290 shown in FIG. 15. Additionally or alternatively, the end 222 may be in electrical connection with UTM features (e.g., UTM feature 276-4) of the second UTM structure 270, as shown in FIG. 12. In addition, one of the outermost UTM features (e.g., UTM feature 266-5) may have an end 224 in electrical connection with an external voltage source.

Referring back to FIG. 7A, the UTM feature 266-1 may have a first width W1a and the UTM feature 266-2 to 266-4 may have a second width W1b that is less than the first width W1a. In some embodiments, the first width W1a is at least twice larger than the second width W1b. In some embodiments, the first width W1a and the second width W1b may have a ratio (W1a:W1b) of about 3:1 to about 6:1. In some embodiments, the UTM feature 266-2 or 266-3 and the UTM feature 266-4 has a line pitch P1 of about 1 μm to about 30 μm, for example about 2.7 μm to about 5 μm. The critical dimension (CD) of the line pitch P1 represents a minimal dimension that could be found in a pattern, such as the coiled pattern shown in FIG. 7A. While not shown, it is contemplated that the first UTM structure 260 may include multiple sets of different line pitch, among which the minimal line pitch can be referred to the critical dimension of a line pitch. In some embodiments, the UTM features 266-1 to 266-4 occupies a surface area A2, whereas the total surface area of the substrate 102 has a surface area A1. It should be noted that the total surface area of the substrate 102 can be a total surface area of an individual die containing the first UTM structure 260 disclosed herein. The area ratio (A2/A1) can be referred to as an area density of the UTM structure. The area density of the UTM is a collective concept of the total UTM surface area to the total surface area of the substrate 102, specifically at the first UTM structure 260. In some embodiments, the surface area A2 is about 50% or less than the surface area A1.

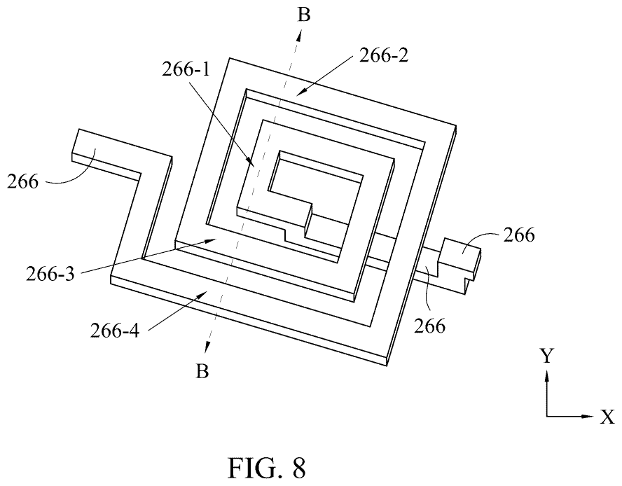

In some embodiments, the UTM feature 266-1 is not a pillar-like structure. Instead, the UTM feature 266-1 is part of the continuous metal line. FIG. 8 is a top view of a portion of the semiconductor device structure 100 showing the first UTM structure 260 taken along cross-section B-B of FIG. 6, in accordance with another embodiment. In this embodiment, the UTM features 266-1 to 266-4 are constructed as a single continuous metal line and is arranged in a planar coil-like pattern. In some embodiments, the UTM feature 266-1 may have a first width and the UTM features 266-2 to 266-4 may have a second width less than the first width.

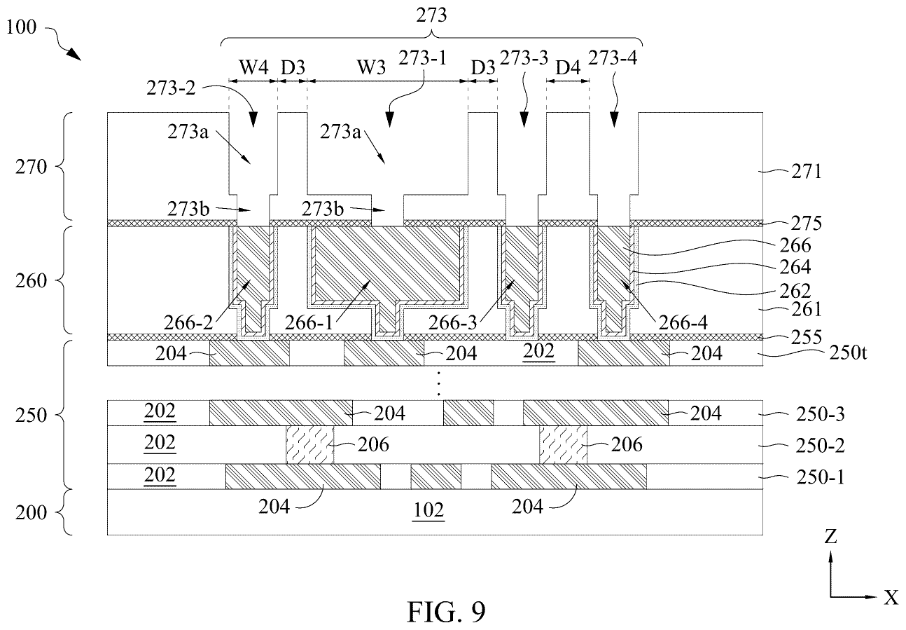

In FIG. 9, a second etch stop layer 275 and a second dielectric material 271 are sequentially formed over the first UTM structure 260. The second etch stop layer 275 may include the same material as the first etch stop layer 255, and the second dielectric material 271 may include the same material as the first dielectric material 261. The second dielectric material 271 may have a thickness between about 1000 Å and about 68000 Å, for example about 8000 Å to about 35000 Å. In some embodiments, the first and second dielectric material 261, 271 have the same thickness. In some embodiments, and the second dielectric material 261, 271 have a thickness different from each other. The first dielectric material 261 may have a first thickness and the second dielectric material 271 may have a second thickness that is less or greater than the first thickness, depending on the surface area of the first and second dielectric materials 261, 271. For example, when the first dielectric material 261 has a surface area greater than that of the second dielectric material 271, the first thickness of the first dielectric material 261 may be less than the second thickness of the second dielectric material 271. When the first dielectric material 261 has a surface area less than that of the second dielectric material 271, the first thickness of the first dielectric material 261 may be greater than the second thickness of the second dielectric material 271.

The second dielectric material 271 and the second etch stop layer 275 are patterned and etched to form openings 273a, 273b. In some embodiments, the openings 273a, 273b are formed to aligned with the location of the UTM features 266-1 to 266-4. The openings 273a, 273b combined form UTM trenches 273-1, 273-2, 273-3, 273-4 (collectively referred to as 273). In some embodiments, the two or more UTM trenches may be part of a continuous trench. Similarly, the UTM trench 273-2 and the UTM trench 273-3 may belong to a continuous trench in some embodiments. In some embodiments, the UTM trenches 273-2, 273-3 is a continuous trench arranged to surround the UTM trench 273-1. While four UTM trenches 273-1 to 273-4 are shown, more or less UTM trenches are contemplated depending on the application. The UTM trenches 273-1 to 273-4 are to be filled with a conductive material to form UTM features therein. The openings 273a, 273b may be formed by any suitable process, such as one or more etch processes. In some embodiments, the openings 273a, 273b are formed as a result of a dual-damascene process. The opening 273a may be a trench opening formed in an upper portion of the second dielectric material 271. The opening 273b may be a via opening formed through the second dielectric material 271 and the second etch stop layer 275 to expose a portion of the corresponding UTM features. For example, the opening 273b of the UTM trench 273-1 is formed to expose the top surface of the UTM feature 266-1, the opening 273b of the UTM trench 273-2 is formed to expose the top surface of the UTM feature 266-2, the opening 273b of the UTM trench 273-3 is formed to expose the top surface of the UTM feature 266-3, and the opening 273b of the UTM trench 273-4 is formed to expose the top surface of the UTM feature 266-4.

Likewise, the UTM trenches 273-1 to 273-4 are formed so that the UTM trench 273-1 and the UTM trenches 273-2 and 273-3 are separated by a distance D3, and the UTM trench 273-3 and the UTM trench 273-4 are separated by a distance D4. In some embodiments, the distance D3 is substantially identical to the distance D4. In some embodiments, the distance D3 is greater or less than the distance D4. The UTM trenches 273-1 to 273-4 may have a width ranging from 0.1 μm to about 10 μm. The UTM trench 273-1 may have a width W3 and the trenches 273-2, 273-3, 273-4 may have a width W4 that is less than the width W3. In some embodiments, the width W3 and width W4 may be at a ratio (W3:W4) of about 2:1 or greater, for example about 3:1 to about 6:1, for example about 4:1. In some embodiments, the width W3 may be in a range of about 0.1 μm to about 10 μm, and the distance D3 may be greater than about 0.2 μm, for example about 1.8 μm or greater.

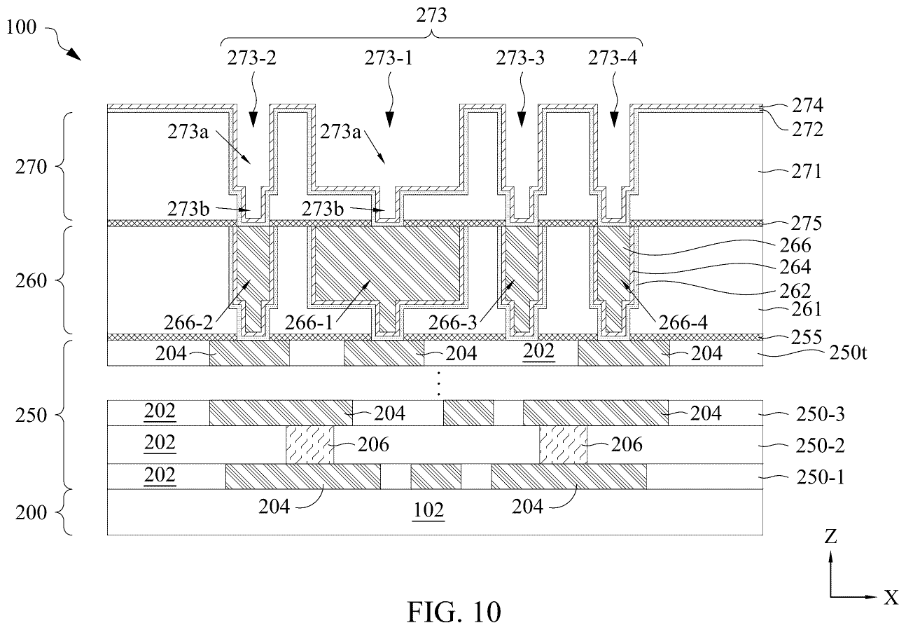

In FIG. 10, a barrier layer 272 and a seed layer 274 are sequentially formed over the exposed surfaces of the second dielectric material 271. The barrier layer 272 and the seed layer 274 may include the same material as the barrier layer 262 and the seed layer 264, respectively, and may be deposited using the same fashion as the barrier layer 262 and the seed layer 264 discussed above.

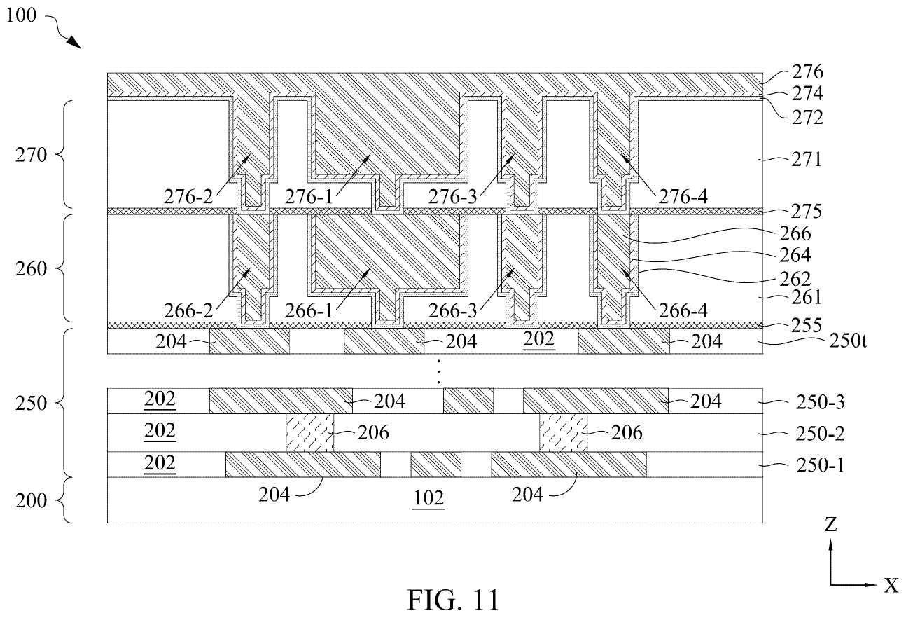

In FIG. 11, an UTM layer 276 is formed on the seed layer 274. Likewise, the UTM layer 276 is deposited until the UTM trenches 273-1 to 273-4 are completely filled. The UTM layer 276 may include the same material as the UTM layer 266, and may be deposited using the same fashion as the UTM layer 266. In some embodiments, the UTM layer 276 formed in the UTM trench 273-1 includes a first electrically conductive material and the UTM layer 276 formed in the UTM trenches 273-2 to 273-4 includes a second electrically conductive material that is different than the first electrically conductive material.

In some embodiments, the UTM layer 276 formed in the UTM trenches 273-1 to 273-4 includes a first electrically conductive material and the UTM layer 266 formed in the UTM trenches 263-1 to 263-4 includes a second electrically conductive material that is different than the first electrically conductive material.

In some embodiments, the UTM layer 276 formed in the UTM trenches 273-1 includes a first electrically conductive material, and the UTM layer 276 formed in the UTM trenches 273-2 to 273-4 and the UTM layer 266 formed in the UTM trenches 263-1 to 263-4 (i.e., the UTM features 266-1 to 266-4) includes a second electrically conductive material that is different than the first electrically conductive material. Alternatively, the UTM layer 276 formed in the UTM trenches 263-1 (i.e., the UTM feature 266-1) includes a first electrically conductive material, and the UTM layer 276 formed in the UTM trenches 273-2 to 273-4 and the UTM layer 266 formed in the UTM trenches 263-2 to 263-4 (i.e., the UTM features 266-2 to 266-4) includes a second electrically conductive material that is different than the first electrically conductive material.

In FIG. 12, a planarization process, such as a CMP process, is performed on the semiconductor device structure 100 until the top surfaces of the second dielectric material 271, the barrier layer 272, the seed layer 274, and the UTM layer 276 are substantially co-planar. The UTM layer 276 in the UTM trenches 273-1 to 273-4 form UTM features 276-1, 276-2, 276-3, 276-4, and the UTM features 276-1 to 276-4 are separated from one another other by the second dielectric material 271. The UTM features 276-1 to 276-4 (and other UTM features, not shown) in the second dielectric material 271 form the second UTM structure 270. The second UTM structure 270 may have a first thickness, and the conductive features (e.g., metal lines 204) in the metal layer M1 250-1 of the interconnect structure 250 may have a second thickness significantly less than the first thickness. In some embodiments, the first thickness may be at least 10 times greater than the second thickness. In various embodiments, the UTM features 276-2 to 276-4 are arranged in a planar coil-like pattern. Similarly, the UTM features 276-1 to 276-4 may form a portion of an inductor. The UTM features 276-1 to 276-4 are electrically connected to the UTM features 266-1 to 266-4. Stacking two layers of the first and second UTM structures 260, 270 can reduce layout area ratio and achieve higher Q inductor. As a result, the RF circuit performance is enhanced.

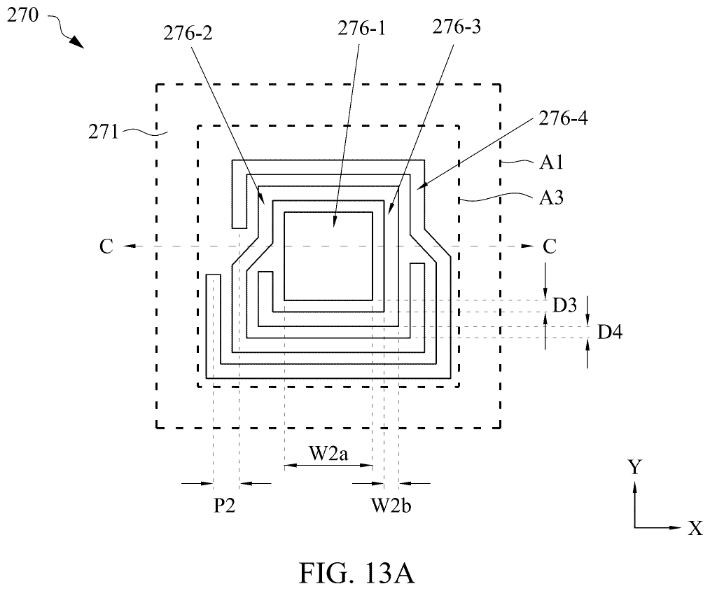

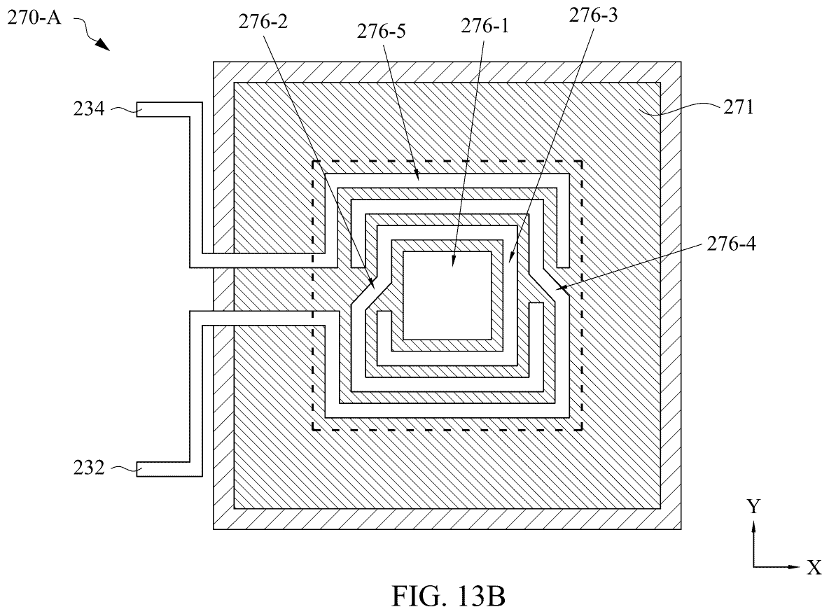

FIG. 13A is a top view of a portion of the semiconductor device structure 100 showing the second UTM structure 270 taken along cross-section C-C of FIG. 12, in accordance with some embodiments. As can be seen, the UTM features 276-2 to 276-4 are discrete metal lines arranged in a planar coil-like pattern. In some embodiments, the UTM features 276-2 and 276-3 are constructed as a continuous metal line surrounding the UTM feature 276-1, and the UTM feature 276-4 is constructed as a continuous metal line around the UTM features 276-2 and 276-3. The UTM features 276-2 to 276-4 may have the same width. The UTM features 276-2 to 276-4 may be arranged asymmetric so that the number of the metal lines on a first side of the UTM feature 276-1 is different than the number of the metal lines on a second side (opposing the first side) of the UTM feature 276-1. The UTM feature 276-1 and the UTM feature 276-2 or 276-3 are separated from each other by the distance D3, and the UTM feature 276-2 or 276-3 and the UTM feature 276-4 are separated from each other by the distance D4. Depending on the application, the distance D3 may be less, equal to, or greater than the distance D4. In some embodiments, the UTM feature 276-1 may be a pillar-like structure in any shape, such as a square-shaped, a round-shaped, a rectangular-shaped, or an oval-shaped pillar when viewing from top. In some embodiments, the UTM feature 276-1 may have a first shape and the UTM feature 266-1 may have a second shape the same or different than the first shape. For example, the UTM feature 276-1 may be a square-shaped pillar, and the UTM feature 266-1 may be a rectangular-shaped pillar.

While not shown, the UTM feature 276-4 may have a first end in electrical connection with conductive terminals, such as conductive structures 290 shown in FIG. 15, and a second end in electrical connection with an external voltage source.

FIG. 13B is a top view of a portion of the semiconductor device structure 100 showing a first UTM structure 270-A, such as the first UTM structure 270, taken along cross-section C-C of FIG. 12, in accordance with some alternative embodiments. In this embodiment, the UTM features 276-2 to 276-4 are arranged in a symmetric manner so that the number of the metal lines on a first side of the UTM feature 276-1 is identical to the number of the metal lines on a second side (opposing the first side) of the UTM feature 276-1. FIG. 13B further shows that one of the outermost UTM features (e.g., UTM feature 276-4) has an end 232 in electrical connection with conductive terminals, such as conductive structures 290 shown in FIG. 15, and one of the outermost UTM features (e.g., UTM feature 276-5) has an end 234 in electrical connection with an external voltage source.

Referring back to FIG. 13A, the UTM feature 276-1 may have a first width W2a and the UTM feature 276-2 to 276-4 may have a second width W2b that is less than the first width W2a. In some embodiments, the first width W2a is at least twice larger than the second width W2b. In some embodiments, the first width W2a and the second width W2b may have a ratio (W2a:W2b) of about 3:1 to about 6:1. In some embodiments, the UTM feature 276-2 or 276-3 and the UTM feature 276-4 has a line pitch P2 of about 1 μm to about 30 μm, for example about 2.7 μm to about 5 μm. While not shown, it is contemplated that the first UTM structure 270 may include multiple sets of different line pitch. In some embodiments, the UTM features 276-1 to 276-4 occupies a surface area A3, whereas the total surface area of the substrate 102 has a surface area A1. As indicated above, the total surface area of the substrate 102 can be a total surface area of an individual die containing the second UTM structure 270 disclosed herein. The layout area ratio (A3/A1) can be referred to as an area density of the UTM structure. The area density of the UTM is a collective concept of the total UTM surface area to the total surface area of the substrate 102, specifically at the first UTM structure 270. In some embodiments, the surface area A3 is about 50% or less than the surface area A1.

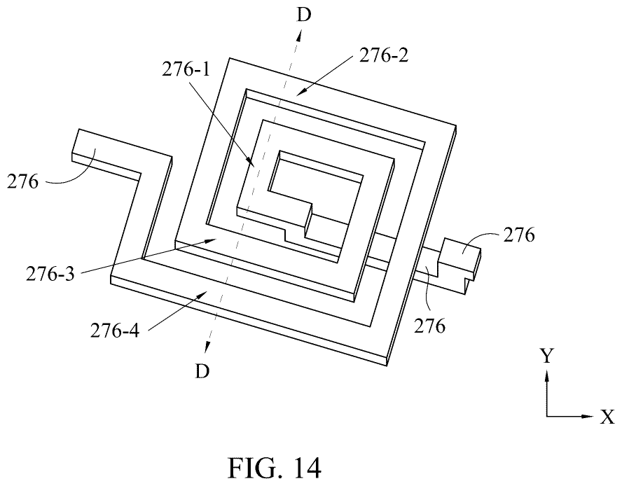

In some embodiments, the UTM feature 276-1 is not a pillar-like structure. Instead, the UTM feature 276-1 is part of the continuous metal line. FIG. 14 is a top view of a portion of the semiconductor device structure 100 showing the first UTM structure 270 taken along cross-section D-D of FIG. 12, in accordance with another embodiment. In this embodiment, the UTM features 276-1 to 276-4 are constructed as a single continuous metal line and is arranged in a planar coil-like pattern. In some embodiments, the UTM feature 276-1 may have a first width and the UTM features 276-2 to 276-4 may have a second width less than the first width.

In some embodiments, the UTM feature 276-1 in the second UTM structure 270 is a pillar-like structure and the UTM feature 266-1 in the first UTM structure 260 is a non-pillar like structure, or vice versa.

In FIG. 15, a dielectric material 282 is sequentially formed over the second UTM structure 270. The dielectric material 282 may include the same material as the dielectric material 261. A portion of the dielectric material 282 may be in contact with the UTM features 276-1 to 276-4 of the second UTM structure 270. After the dielectric material 282 is formed, an etch process, such as a dry etch, a wet etch, or a combination thereof, is performed to form an opening in the dielectric material 282. The openings are arranged so that various UTM features in the second UTM structure 270 are electrically connected to subsequent conductive terminals, such as conductive structures 290. For example, an end of the UTM feature, such as the UTM feature 276-2, may be connected to a conductive pad (not shown), which is connected to the conductive structure 290. Additionally or alternatively, a portion of the UTM feature, such as the UTM feature 276-4, may be connected to the conductive structure 290. Optionally, a passivation layer (not shown) may be formed between the conductive structure 290 and the dielectric material 282. The passivation layer may be made of non-organic materials, such as silicon oxide, un-doped silicate glass, silicon oxynitride, solder resist (SR), silicon nitride, HMDS (hexamethyldisilazane), or the like. In some embodiments, the passivation layer is made of a polymer material, such as polyimide (PI), epoxy, or fluorine-containing polymer. After the passivation layer is formed, a patterning process is performed to form openings that expose a portion of the UTM features.

In either case, a conductive material, such as Cu, Au, Ag, Sn, alloys thereof, or other suitable materials, is formed in the openings (in the dielectric material 282 and/or the passivation layer) to form conductive structures 290. The conductive structures 290 may be a ball-like bump or a pillar. In some cases, the conductive structures 290 are electrically connected to various UTM features in the second UTM structure 270. In some cases, the conductive structures 290 are electrically connected to various UTM features in the first UTM structure 260 through redistribution pad (not shown) and the vias (not shown). The conductive structures 290 are in electrical connection to a voltage source (not shown). In some embodiments, the first UTM structure 260 or the second UTM structure 270 is a discrete inductor, which is not connected to various devices in the device layer 200 and/or conductive features in the interconnect structure 250 through the UTM features (e.g., UTM features 266-1 to 266-4 or UTM features 276-1 to 276-4), but rather through external connections. External connections can be in a form of a wire bond connecting one end of the discrete inductor to a voltage source and the other end to various devices in the device layer 200 and/or conductive features in the interconnect structure 250.

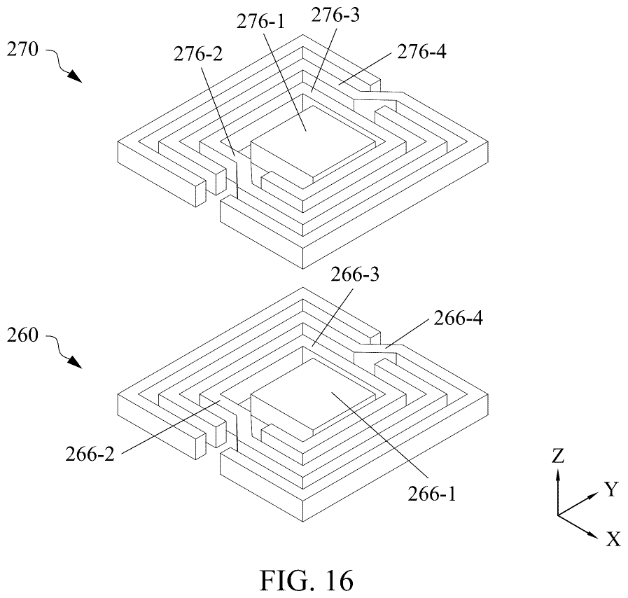

FIG. 16 illustrates a perspective view of a portion of the first UTM structure 260 and a portion of the second UTM structure 270, in accordance with the embodiment shown in FIG. 15. As can be seen, the UTM features 266-2 to 266-4 arranging in a planar coil-like pattern are disposed to surround the UTM feature 266-1, and the UTM features 266-2 to 266-4 are arranged to have a first number of turns. The UTM features 276-2 to 276-4 arranging in a coil-like pattern are disposed to surround the UTM feature 276-1, and the UTM features 276-2 to 276-4 are arranged to have a second number of turns. In some embodiments, the UTM feature 266-1 and the UTM feature 276-1 have substantially the same surface area, and the first number of turns are substantially identical to the second number of turns.

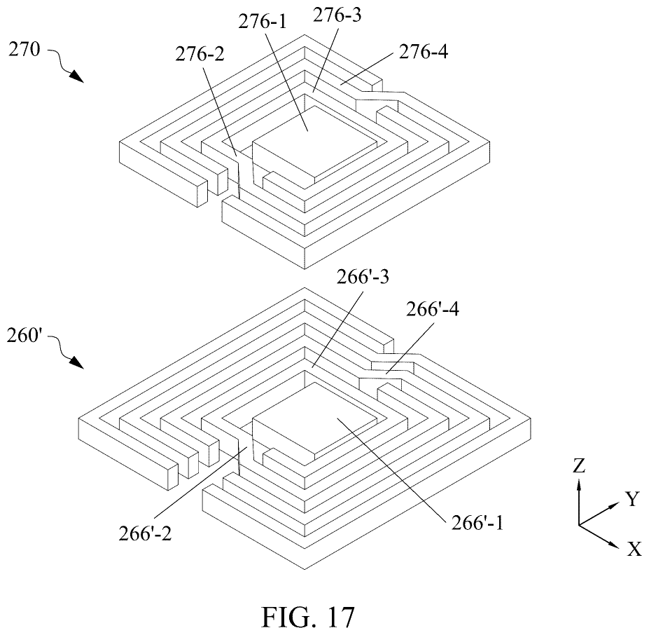

In some embodiments, the UTM features 266-2 to 266-4 and the UTM features 276-2 to 276-4 are arranged such that the first number of turns are different than the second number of turns, and the UTM feature 266-1 and the UTM feature 276-1 have substantially the same surface area. FIG. 17 illustrates an exemplary configuration of the UTM structures in which an UTM structure 260′, such as the UTM structure 260, is disposed below the UTM structure 270 and has a first number of turns greater than the second number of turns of the UTM structure 270. That is, the UTM features 266′-1 to 266′-4 occupy a surface area greater than the surface area of the UTM features 276-1 to 276-4 of the UTM structure 270. In some embodiments, the first number of turns is 4 or greater and the second number of turns is 3 or greater. The arrangement shown in FIG. 17 allows easy routing of connection for the UTM structure 270 since UTM structure 260′ has a greater surface area than the UTM structure 270.

In some embodiments, the UTM feature 266′-1 may have a first surface area and the UTM feature 276-1 may have a second surface area less than the first surface area. Alternatively, the UTM feature 266′-1 may have a first surface area and the UTM feature 276-1 may have a second surface area greater than the first surface area. A larger size of the UTM feature 266′-1 can help lower overall DC resistance for the inductor.

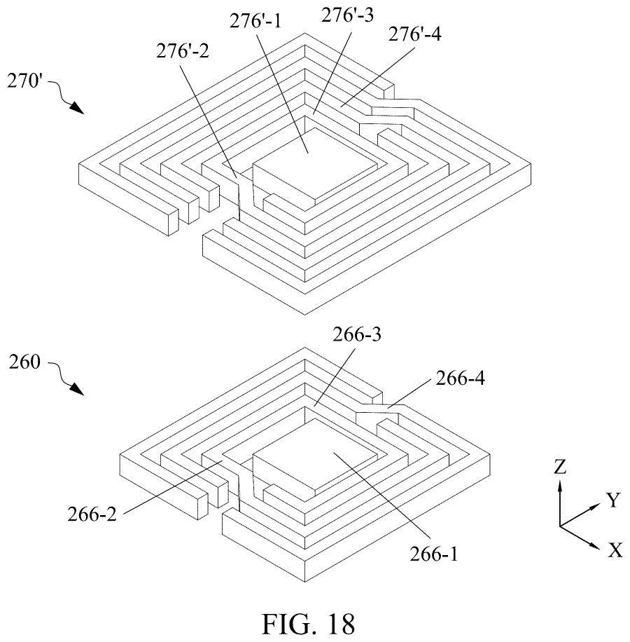

In some embodiments, the UTM features 266-2 to 266-4 and the UTM features 276-2 to 276-4 are arranged such that the first number of turns are less than the second number of turns, and the UTM feature 266-1 and the UTM feature 276-1 have substantially the same surface area. FIG. 18 illustrates an exemplary configuration of the UTM structures in which an UTM structure 270′, such as the UTM structure 270, is disposed over the UTM structure 260 and has a second number of turns greater than the first number of turns of the UTM structure 260. That is, the UTM features 266-1 to 266-4 occupy a surface area that is smaller than the surface area of the UTM features 276′-1 to 276′-4. In some embodiments, the first number of turns is 3 or greater and the second number of turns is 4 or greater. The arrangement shown in FIG. 18 can help minimize parasitic of the inductor to the device layer 200 since the larger size of the UTM structure 270′ is disposed further away from the device layer 200. As a result, the parasitic capacitance between the UTM structure 270′ and various circuit devices in the device layer 200 is lower.

In some embodiments, the UTM feature 276′-1 may have a first surface area and the UTM feature 266-1 may have a second surface area less than the first surface area. A larger size of the UTM feature 276′-1 can help lower overall DC resistance for the inductor. Alternatively, the UTM feature 276′-1 may have a first surface area and the UTM feature 266-1 may have a second surface area greater than the first surface area.

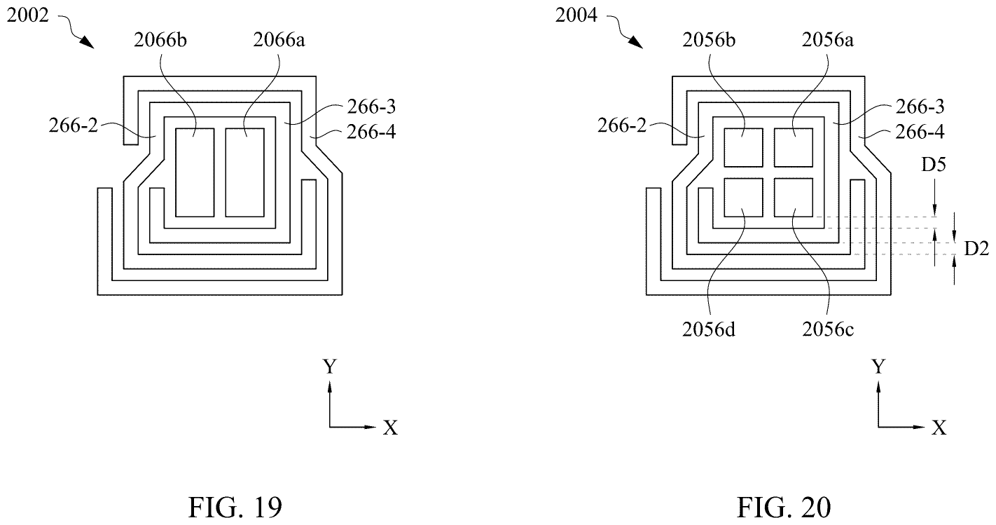

FIG. 19 illustrates an exemplary arrangement of a top-view of an UTM structure 2002, in accordance with some embodiments. The configuration of the UTM structure 2002 may be applied to the first UTM structure 260 and/or the second UTM structure 270. The UTM structure 2002 is substantially identical to the first UTM structure 260 of FIG. 7A except that the UTM feature 266-1 is dividing into two pillar structures, i.e., a first pillar structure 2066a and a second pillar structure 2066b. The first and second pillar structures 2066a, 2066b may each have a rectangular shape extending along the Y-direction. In some embodiments, the first and second pillar structures 2066a, 2066b may each have a rectangular shape extending along the X-direction. In some embodiments, the first pillar structure 2066a may have a rectangular shape extending a first direction and the second pillar structure 2066b may have a rectangular shape extending a second direction that is different than the first direction. In some embodiments, the first pillar structure 2066a may have a first shape (e.g., rectangular-like) and the second pillar structure 2066b may have a second shape (e.g., square-like) that is different than the first shape. The combination of various arrangements of the first and second pillar structures 2066a, 2066b can increase magnetic permeability for the inductor.

FIG. 20 illustrates an exemplary arrangement of a top-view of an UTM structure 2004, in accordance with some embodiments. The configuration of the UTM structure 2004 may be applied to the first UTM structure 260 and/or the second UTM structure 270. The UTM structure 2004 is substantially identical to the first UTM structure 260 of FIG. 7A except that the UTM feature 266-1 is dividing into four pillar structures, i.e., a first pillar structure 2056a, a second pillar structure 2056b, a third pillar structure 2056c, and a fourth pillar structure 2056d. Each pillar structure is separated from the most inner loop of metal line (e.g., UTM feature 266-2 and 266-3) by a distance D5, which may be greater or less than the distance D4 (FIG. 7A). The combination of various arrangements of the pillar structures 2056a-2056d can increase magnetic permeability for the inductor.

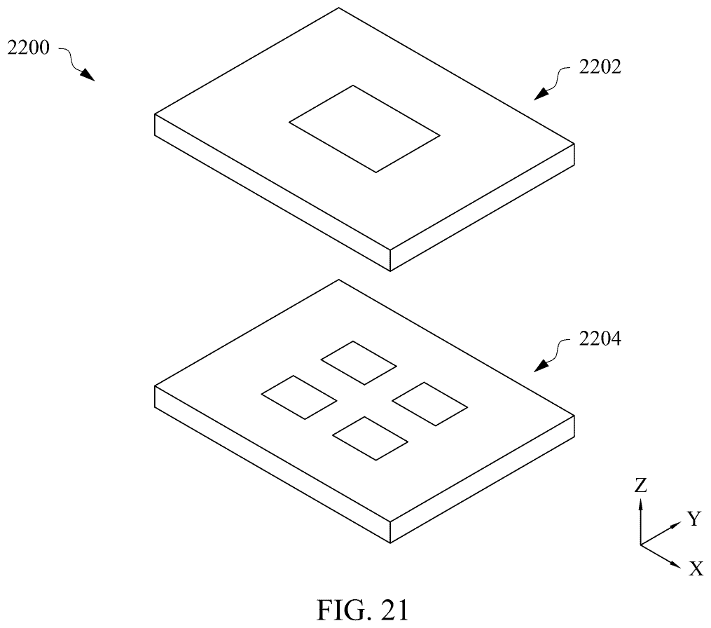

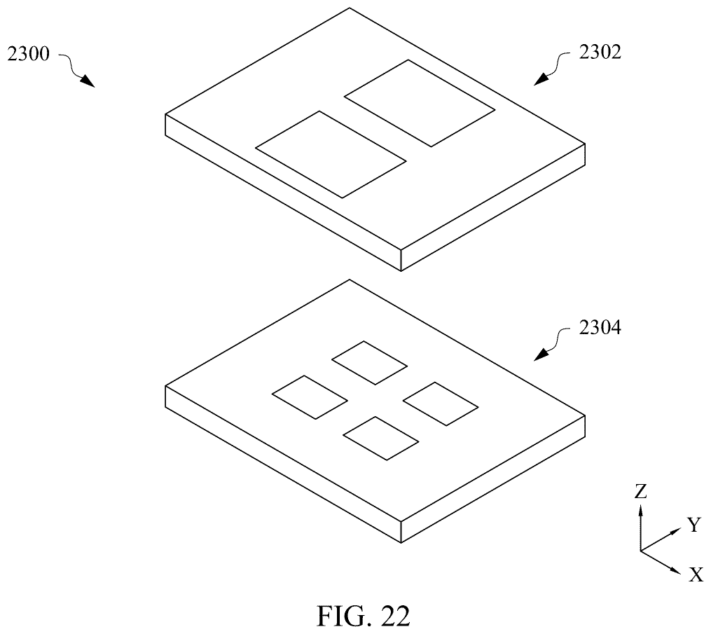

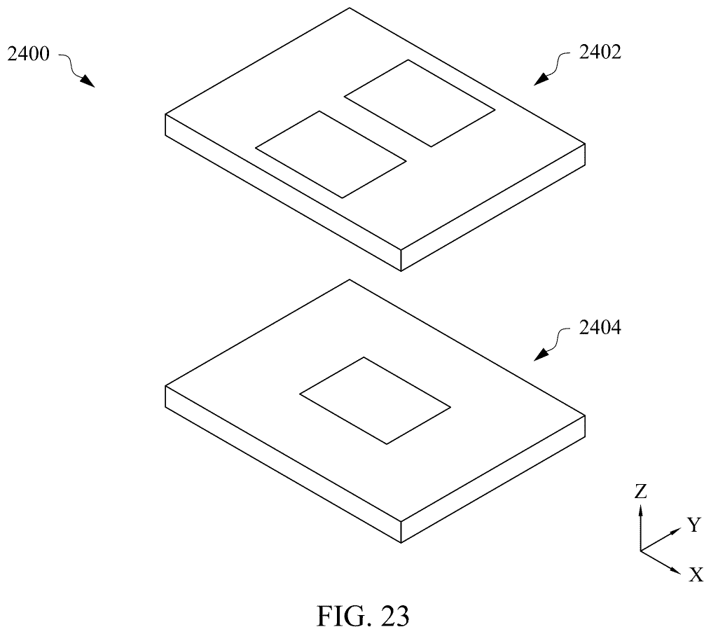

Various UTM structures discussed herein may have a different combination to help increase magnetic permeability for the inductor. FIG. 21 illustrates a schematic configuration of an UTM structure 2200 in accordance with some alternative embodiments. In this embodiment, a first UTM structure 2202, such as the UTM structure 270 of FIG. 13, is disposed over a second UTM structure 2204, such as the UTM structure 2004 of FIG. 20. FIG. 22 illustrates a schematic configuration of an UTM structure 2300 in accordance with some alternative embodiments. In this embodiment, a first UTM structure 2302, such as the UTM structure 2002 of FIG. 19, is disposed over a second UTM structure 2304, such as the UTM structure 2004 of FIG. 20. FIG. 23 illustrates a schematic configuration of an UTM structure 2400 in accordance with some alternative embodiments. In this embodiment, a first UTM structure 2402, such as the UTM structure 2002 of FIG. 19, is disposed over a second UTM structure 2404, such as the UTM structure 2004 of FIG. 20. While not shown, it is contemplated that the size of the upper and lower UTM structures in FIGS. 21-23 can be different from each other. In addition, while two UTM structures are shown in various embodiments of this disclosure, three or more UTM structures with a similar design are contemplated.

Embodiments of the present disclosure provide an improved semiconductor device structure (e.g., RF device) having an inductor constructed in the form of two vertically stacked ultra-thick-metal (UTM) structures. Each UTM structure has a plurality of UTM features arranged in a coil pattern surrounding a pillar-like UTM feature to help reduce layout area ratio at a lower cost due to enlarged routing flexibility. The pillar-like UTM feature has a larger surface area to increase magnetic permeability and magnetic field intensity of the inductor. As a result, a higher Q inductor can be obtained, and the RF circuit performance is enhanced.

An embodiment is a semiconductor device structure. The structure includes a device layer, an interconnect structure comprising a plurality of back-end-of-line (BEOL) metal layers disposed over the device layer, and an ultra-thick-metal (UTM) structure disposed over the interconnect structure. The UTM structure includes a first UTM feature having a first width, and a second UTM feature disposed around the first UTM feature, wherein the second UTM feature has a second width less than the first width, and the second UTM feature is separated from the first UTM feature by a dielectric material.

Another embodiment is a semiconductor device structure. The structure includes an interconnect structure comprising a plurality of back-end-of-line (BEOL) metal layers disposed over a device layer, a first ultra-thick-metal (UTM) structure disposed over the interconnect structure. The first UTM structure includes a first UTM feature, and a second UTM feature disposed around the first UTM feature, wherein the second UTM feature is separated from the first UTM feature by a first dielectric material. The structure also includes a second UTM structure disposed over the first UTM structure, wherein the second UTM structure includes a third UTM feature, and a fourth UTM feature disposed around the third UTM feature, wherein the second UTM feature is separated from the first UTM feature by a second dielectric material.

Another embodiment is a method for forming a semiconductor device structure. The method includes forming an interconnect structure over a device layer, forming a first ultra-thick-metal (UTM) structure over the interconnect structure, wherein the first UTM structure comprises a first UTM feature, a second UTM feature disposed around the first UTM feature, and a first dielectric material separating the first and second UTM features. The method also includes forming a second UTM structure over the first UTM structure, wherein the second UTM structure comprises a third UTM feature, a fourth UTM feature disposed around the third UTM feature, and a second dielectric material separating the third and fourth UTM features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a device layer;
an interconnect structure comprising a plurality of back-end-of-line (BEOL) metal layers disposed over the device layer; and
an ultra-thick-metal (UTM) structure disposed over the interconnect structure, the UTM structure comprising:
a first UTM feature having a first width; and
a second UTM feature disposed around the first UTM feature, wherein the second UTM feature has a second width less than the first width, and the second UTM feature is separated from the first UTM feature by a dielectric material.

2. The semiconductor device structure of claim 1, wherein the first UTM feature is a pillar-like structure.

3. The semiconductor device structure of claim 1, wherein the first UTM feature comprises two or more pillar-like structures.

4. The semiconductor device structure of claim 2, wherein the second UTM feature comprises a plurality of discrete metal lines.

5. The semiconductor device structure of claim 4, wherein the second UTM feature is arranged in a coil-like pattern.

6. The semiconductor device structure of claim 4, wherein the plurality of metal lines has the same width.

7. The semiconductor device structure of claim 4, wherein the number of the metal lines of the second UTM feature on a first side of the first UTM feature is different than the number of the metal lines of the second UTM feature on a second side of the first UTM feature.

8. The semiconductor device structure of claim 1, wherein the BEOL metal layer disposed immediately above the device layer has a first thickness, and the UTM structure has a second thickness that is greater than the first thickness.

9. The semiconductor device structure of claim 1, wherein the first UTM feature is formed of a first electrically conductive material and the second UTM feature is formed of a second electrically conductive material that is chemically different than the first electrically conductive material.

10. A semiconductor device structure, comprising:
an interconnect structure comprising a plurality of back-end-of-line (BEOL) metal layers disposed over a device layer;
a first ultra-thick-metal (UTM) structure disposed over the interconnect structure, the first UTM structure comprising:
a first UTM feature; and
a second UTM feature disposed around the first UTM feature, wherein the second UTM feature is separated from the first UTM feature by a first dielectric material; and
a second UTM structure disposed over the first UTM structure, the second UTM structure comprising:
a third UTM feature; and
a fourth UTM feature disposed around the third UTM feature, wherein the fourth UTM feature is separated from the third UTM feature by a second dielectric material.

11. The semiconductor device structure of claim 10, wherein a bottommost BEOL metal layer in the interconnect structure has a first thickness, and the first and second UTM features have a second thickness that is greater than the first thickness.

12. The semiconductor device structure of claim 10, wherein the first and third UTM features are aligned.

13. The semiconductor device structure of claim 10, wherein the first and third UTM features are a pillar-like structure.

14. The semiconductor device structure of claim 13, wherein the first UTM feature has a first number of pillar-like structure and the second UTM feature has a second number of pillar-like structure different than the first number.

15. The semiconductor device structure of claim 13, wherein each of the second and fourth UTM features comprises a plurality of discrete metal lines.

16. The semiconductor device structure of claim 14, wherein the second and fourth UTM features are arranged in a coil-like pattern.

17. The semiconductor device structure of claim 16, wherein the second UTM features are arranged to have a first number of turns, and the fourth UTM features are arranged to have a second number of turns different than the first number of turns.

18. A method for forming a semiconductor device structure, comprising:
forming an interconnect structure over a device layer;
forming a first ultra-thick-metal (UTM) structure over the interconnect structure, wherein the first UTM structure comprises a first UTM feature, a second UTM feature disposed around the first UTM feature, and a first dielectric material separating the first and second UTM features; and
forming a second UTM structure over the first UTM structure, wherein the second UTM structure comprises a third UTM feature, a fourth UTM feature disposed around the third UTM feature, and a second dielectric material separating the third and fourth UTM features.

19. The method of claim 18, wherein the first and third UTM features have a first width, and the second and fourth UTM features have a second width less than the first width.

20. The method of claim 18, wherein the second UTM features are arranged in a coil-like pattern having a first number of turns, and the fourth UTM features are arranged in a coil-like pattern having a second number of turns that is different than the first number of turns.
